(19) United States
(12) Patent Application Publication
(10) Pub. No.: US 2016/0252767 A1
(43) Pub. Date: Sep. 1, 2016

(54) COLOR FILTER SUBSTRATE AND DISPLAY DEVICE

(71) Applicant: SHENZHEN CHINA STAR OPTOELECTRONICS TECHNOLOGY CO. , LTD., Shenzhen, Guangdong (CN)

(72) Inventor: Qibiao LV, Shenzhen (CN)

(21) Appl. No.: 14/383,014

(22) PCT Filed: Jun. 10, 2014
(86) PCT No.: PCT/CN2014/079610

§ 371 Date: Sep. 4, 2014

(30) Foreign Application Priority Data
May 29, 2014 (CN) 201410235518.3

(51) Int. Cl. G02F 1/1339; H01L 29/786; H01L 27/12; G02F 1/1335; G02F 1/1362

(52) U.S. Cl. CPC G02F 1/13394; G02F 1/133514; G02F 1/133512; G02F 1/136286; H01L 27/124; H01L 27/1222; H01L 29/78669; G02F 2001/13396

(57) ABSTRACT

The present invention relates to the technical field of display, in particular to a color filter substrate and a display device. By means of which, the technical problem of light leakage caused by alignment deviation of the array substrate and the color filter substrate in the box aligning process can be solved. A color filter substrate, including a plurality of spacers, wherein at least one of the spacers is arranged at each of both sides of a data line on an array substrate. The present invention can be applied into LCD televisions, LCD displays, cell phones and flat panel computers.

The present disclosure claims the priority of Chinese Patent Application CN 201410235518.3, filed on May 29, 2014 and entitled “COLOR FILTER SUBSTRATE AND DISPLAY DEVICE”, the entire contents of which are herein incorporated by reference.

### FIELD OF THE INVENTION

The present disclosure relates to the technical field of display, in particular to a color filter substrate and a display device.

### BACKGROUND OF THE INVENTION

With the development of display technology, a liquid crystal display has become the most common flat panel display device. In the manufacturing process of the liquid crystal display, an array substrate and a color filter substrate are independently produced, and then subjected to box aligning so as to form a liquid crystal box. In the box, a black matrix on the color filter substrate corresponds to the positions of components on the array substrate, such as scan lines (gate lines), data lines, thin film transistors (MT) and the like, in order to shield the components such as the scan lines, the data lines, the TFTs and the like.

However, in the box aligning process of the array substrate and the color filter substrate, particularly for a large-sized liquid crystal display, alignment deviation often occurs between the array substrate and the color filter substrate, so that the black matrix is dislocated with the components such as the scan lines, the data lines, the TFTs and the like. Among others, the condition that the black matrix is dislocated with the data lines is relatively frequent, so that light will leak from one side of the data lines. Therfore, a V-crosstalk phenomenon is generated, and the display effect of the liquid crystal display is affected.

### SUMMARY OF THE INVENTION

The present disclosure aims to provide a color filter substrate and a display device, for solving the technical problem of light leakage caused by alignment deviation of an array substrate and the color filter substrate in the box aligning process.

The present disclosure provides a color filter substrate, including a plurality of spacers, wherein at least one of the spacers is arranged at each of both sides of a data line on an array substrate.

Preferably, the difference between the distance between the spacers arranged at respective sides of the data line and the width of the data line is 2 to 5 microns.

Preferably, spacers in form of paired ones are arranged at respective side of the data line, with one spacer being arranged at each side of the data line.

Optionally, the paired spacers are paired primary spacers or paired secondary spacers.

Preferably, the paired spacers are all paired secondary spacers, and the color filter substrate further includes primary spacers arranged on a substrate, the primary spacers corresponding to bosses on the array substrate in positions.

Or, the paired spacers are all paired primary spacers, and the color filter substrate further includes secondary spacers arranged on the substrate, the primary spacers being higher than the secondary spacers.

The present disclosure further provides a display device, including an array substrate and the above-mentioned color filter substrate. In the device, scan lines and data lines are arranged on the array substrate in a crisscross manner, corresponding to the positions of the spacers arranged on both sides of the data lines, and also corresponding to the positions where the scan lines are overlapped with the data lines. And at the overlapping positions, the data lines are located above the scan lines, with a gate insulating layer being arranged between the data lines and the scan lines.

Or, a semiconductor layer and a doped semiconductor layer are further arranged between the data lines and the gate insulating layer.

Further, bosses are arranged on the array substrate.

Further, each boss is formed by the semiconductor layer, the doped semiconductor layer and a metal layer.

The present disclosure brings the following beneficial effects. The color filter substrate provided by the present disclosure includes a plurality of spacers, and at least one spacer is arranged at each of two sides of a data line on the array substrate. Because the data line itself on the array substrate has a certain thickness, the data line itself is higher than two side areas thereof. In the box aligning process of the color filter substrate according to the embodiment of the present disclosure and the array substrate, the data line is inserted into a groove formed between the spacers respectively located on both sides of the data line, so that the data line will be clamped between the two spacers. In this way, the data line can be positioned through the spacers arranged at both sides of the data line, so that the data line may be accurately aligned with the black matrix. Therefore, the technical problem of light leakage caused by alignment deviation of the array substrate and the color filter substrate in the box aligning process can be solved.

Other features and advantages of the present disclosure will be set forth in the following description, and in part will be self-evident from the description, or be learned through implementing the present disclosure. The objectives and other advantages of the present disclosure may be achieved and obtained by structures particularly pointed out in the description, the claims and the accompanying drawings.

### BRIEF DESCRIPTION OF THE DRAWINGS

To illustrate the technical solutions in the embodiments of the present disclosure more clearly, a brief introduction on the accompanying drawings which are used in the following embodiments is provided below:

FIG. 1 is a schematic diagram of a display device according to embodiment I of the present disclosure;

FIG. 2 shows the cross-sectional view along A-A direction in FIG. 1;

FIG. 3 is a cross-sectional view of a display device according to embodiment II of the present disclosure;

FIG. 4 is a schematic diagram of a display device according to embodiment III of the present disclosure; and

FIG. 5 shows the cross-sectional view along A-A direction in FIG. 4.

### DETAILED DESCRIPTION OF THE EMBODIMENTS

A detailed description of the implementation of the present disclosure will be given below, in combination with the accompanying drawings and embodiments, therefore, an implementation process of how to use technical means of the present disclosure to solve technical problems and achieve a technical effect may be fully understood and implemented accordingly. It should be noted that, as long as no conflict is generated, various embodiments of the present disclosure and various features of the embodiments may be combined with each other, and the formed technical solutions are all within the protection scope of the present disclosure.

### Embodiment I

As shown in FIG. 2, a color filter substrate 1 according to the present disclosure includes a substrate 10, and a filter layer (not shown in the figure), a black matrix 11, a common electrode 12 and a plurality of spacers 14 which are arranged on the substrate 10. In the color filter substrate 1, at least one spacer 14 is arranged at each of both sides of a data line 22 on an array substrate 2.

Because the data line 22 itself on the array substrate 2 has a certain thickness, the data line 22 itself is higher than two side areas thereof. In the box aligning process of the color filter substrate 1 according to the embodiment of the present disclosure and the array substrate 2, the data line 22 is inserted into a groove formed between the spacers 14 respectively located on both sides of the data line 22, so that the data line 22 will be clamped between the two spacers 14. In this way, the data line 22 can be positioned through the spacers 14 arranged at both sides of the data line 22, so that the data line 22 may be accurately aligned with the black matrix 11. Therefore, the technical problem of light leakage caused by alignment deviation of the array substrate and the color filter substrate in the box aligning process can be solved.

As a preferred solution, spacers 14 in form of paired ones are arranged at both sides of the data line 22, and a pair of spacers 14 are located at both sides of the data line 22 respectively.

The distance between the pair of spacers 14 arranged at both sides of the data line 22 depends on the width of the data line on the array substrate. In the practical manufacturing process, it is very difficult to ensure that the distance between the pair of spacers 14 is exactly equal to the width of the data line. Therefore, the distance between the pair of spacers 14 may be slightly greater than the width of the data line. The difference between the distance between the pair of spacers 14 and the width of the data line is preferably 2 to 5 microns. Therefore, the pair of spacers 14 can clamp the data line tightly as much as possible, so as to ensure that the alignment between the data line and the black matrix 11 is more accurate.

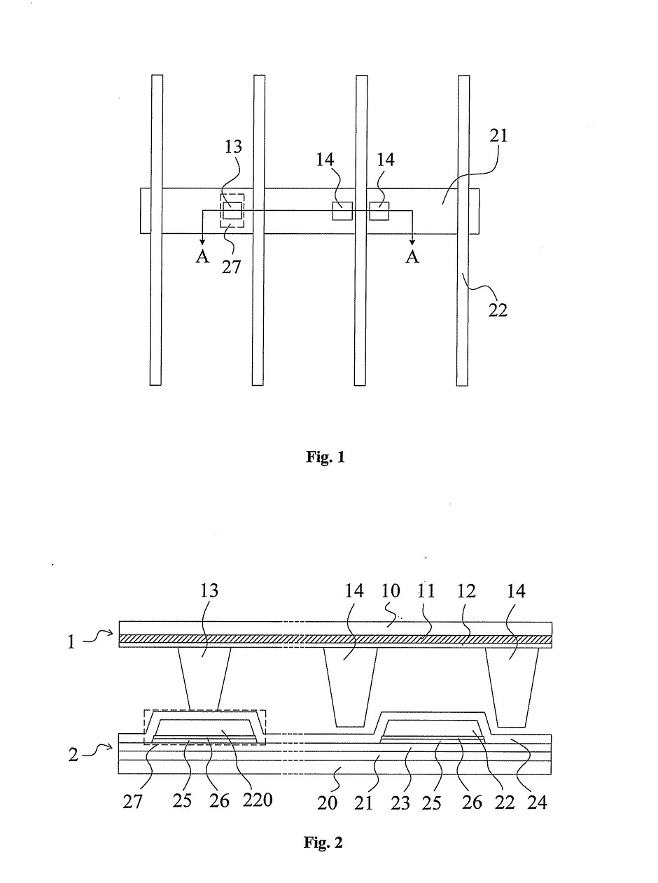

As shown in FIG. 1 and FIG. 2, the embodiment of the present disclosure further provides a display device, which may be a liquid crystal television, a liquid crystal display, a mobile phone, a flat panel computer and the like. The display device includes an array substrate 2 and the above color filter substrate 1 provided by this embodiment. The spacers on the color filter substrate 1 generally may be divided into primary spacers and secondary spacers. In this embodiment, the paired spacers are paired secondary spacers 14, and the primary spacers 13 may be arranged on the substrate 10 in an individual manner (unpaired).

The array substrate 2 includes scan lines 21 and data lines 22 arranged on a substrate 20 in a crisscross manner, as well as a gate insulating layer 23, a passivation layer 24 and the like. The primary spacers 13 and the secondary spacers 14 on the color filter substrate 1 are all located within the region of the scan lines 21, corresponding to the positions of the paired secondary spacers 14 arranged on the respective sides of the data lines 22, and also corresponding to the positions where the scan lines 21 are overlapped with the data lines 22. In this embodiment, at the positions where the scan lines 21 are overlapped with the data lines 22, the data lines 22 are located above the scan lines 21. The gate insulating layer 23, a semiconductor layer (an amorphous silicon layer) 25 and a doped semiconductor layer (n-type amorphous silicon layer) 26 are sequentially arranged between the data lines 22 and the scan lines 21. The array substrate 2 with such a structure is manufactured through four times of mask patterning process.

Moreover, bosses 27 for supporting the primary spacers 13 are also arranged on the array substrate 2, and the primary spacers 13 correspond to the positions of bosses 27 on the array substrate 2. Each boss 27 is formed by the semiconductor layer 25, the doped semiconductor layer 26 and a metal layer 220 located on the gate insulating layer 23. The metal layer 220 and the data lines 22 are located on the same layer. Therefore, in the manufacturing process of the array substrate 2, the metal layer 220 and the data lines 22 may be formed synchronously; and the bosses 27 are as high as the data lines 22.

In this embodiment, before box aligning of the color filter substrate 1 and the array substrate 2, the primary spacers 13 are as high as the secondary spacers 14, so that the primary spacers 13 and the secondary spacers 14 may be synchronously formed on the substrate 10.

In the box aligning process of the color filter substrate 1 and the array substrate 2, the free ends of the primary spacers 13 will abut against the bosses 27 on the array substrate 2. The primary spacers 13 are compressed under the action of pressure, while the secondary spacers 14 are not yet in contact with the array substrate 2, so that the height of the primary spacers 13 becomes smaller than that of the secondary spacers 14. Because the bosses 27 are as high as the data lines 22, the free ends of the secondary spacers 14 will be lower than the upper edges of the data lines 22 at this moment, and thus the data lines 22 would be inserted into grooves formed by the paired secondary spacers 14 respectively. Therefore, each data line 22 will be clamped between a pair of secondary spacers 14. In this way, the data lines 22 can be positioned through the paired secondary spacers 14, so that the data lines 22 may be accurately aligned with the black matrix 11. Therefore, the technical problem of light leakage caused by alignment deviation of the array substrate and the color filter substrate in the box aligning process can be solved.

After box aligning of the color filter substrate 1 and the array substrate 2, general, only the primary spacers 13 are in contact with the bosses 27 on the array substrate 2 to play a main supporting role and maintain the box thickness between the color filter substrate 1 and the array substrate 2, whereas the secondary spacers 14 are not in contact with the array substrate 2. When the color filter substrate 1 is subjected to an external pressure, the secondary spacers 14 are in contact with the array substrate 2 to play an auxiliary supporting role.

Generally, there are more secondary spacers and fewer primary spacers on the color filter substrate. Moreover, in the prior art, a secondary spacer or a primary spacer is arranged on one side of a data line at the position where each scan line is overlapped with the data line. The color filter substrate according to the embodiment of the present disclosure can be realized without changing the quantity of the existing primary spacers and secondary spacers. Specifically, only the positions of the secondary spacers need to be changed so that the original separated secondary spacers are re-combined with each other into paired secondary spacers, the data lines can be positioned through the paired secondary spacers. Therefore, the technical problem of light leakage caused by alignment deviation of the array substrate and the color filter substrate in the box aligning process can be solved.

Of course, in order to achieve a better technical effect, the quantity of the secondary spacers may be appropriately increased. For example, two or more pairs of secondary spacers may be arranged at the positions where the scan lines are overlapped with the data lines, to enhance the effect of positioning the data lines through the paired secondary spacers.

### Embodiment II

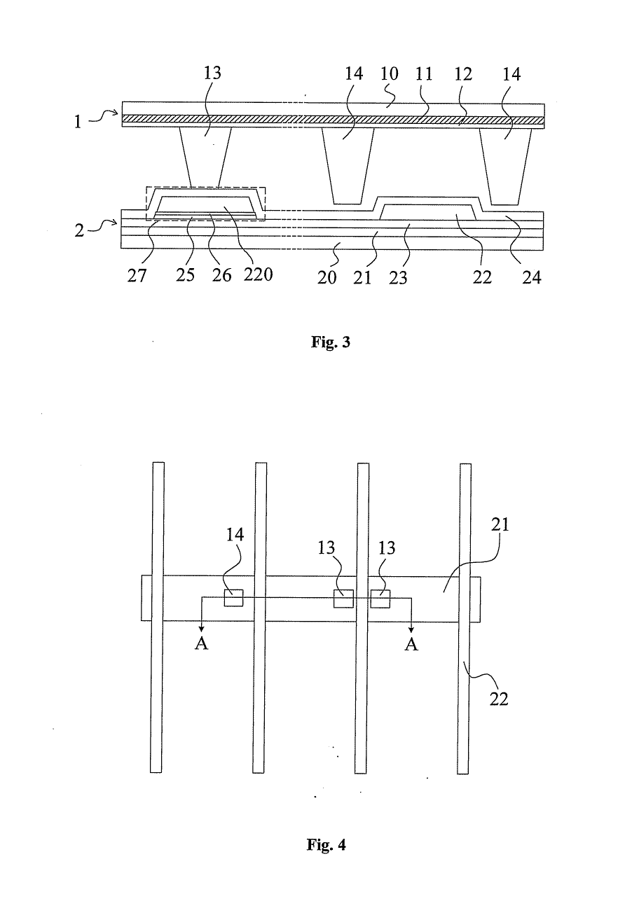

This embodiment is substantially the same as embodiment I, and the difference therebetween lies in that as shown in FIG. 3, in the array substrate 2 of this embodiment, data lines 22 are located above the scan lines 21 at the positions where the scan lines 21 are overlapped with the data lines 22, with only a gate insulating layer 23 being arranged between the data lines 22 and the scan lines 21. The array substrate 2 with such a structure can be manufactured through five times of mask patterning process.

Since the semiconductor layer and the doped semiconductor layer are very thin (compared with the data lines), the data lines 22 in this embodiment are substantially as high as those in embodiment I. Therefore, in this embodiment, the paired secondary spacers can also play a role in positioning the data lines 22 satisfactory, so that the data lines 22 can be accurately aligned with the black matrix 11 to achieve the same technical effect as embodiment I.

### Embodiment III

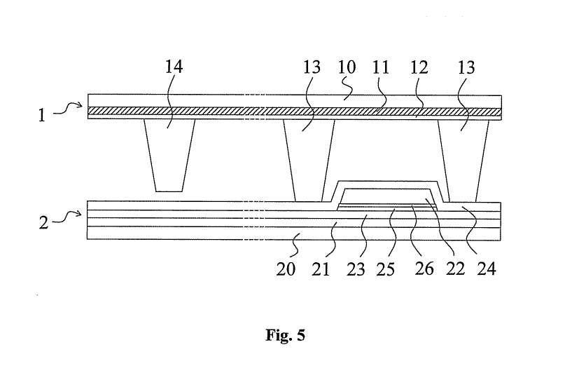

As shown in FIG. 4 and FIG. 5, a color filter substrate 1 provided by the embodiment of the present disclosure includes a substrate 10, and a filter layer (not shown in the figures), a black matrix 11, a common electrode 12 and a plurality of spacers 13 which are arranged on the substrate 10. Among others, the paired spacers 13 are arranged at both sides of data lines 22 on an array substrate 2, and a spacer 13 is arranged at each side of a data line 22.

In this embodiment, the paired spacers are paired primary spacers 13, and the color filter substrate 1 further includes separated (unpaired) secondary spacers 14 arranged on the substrate 10, with the primary spacers 13 being higher than the secondary spacers 14.

The embodiment of the present disclosure further provides a display device, including an array substrate 2 and the above color filter substrate 1 provided by this embodiment.

In the display device, the array substrate 2 includes scan lines 21 and data lines 22 arranged on a substrate 20 in a crisscross manner, as well as a gate insulating layer 23, a passivation layer 24 and the like. The primary spacers 13 and the secondary spacers 14 on the color filter substrate 1 are located within the region of the scan lines 21, corresponding to the positions of the paired secondary spacers 14 on both sides of the data lines 22, and also corresponding to the positions where the scan lines 21 are overlapped with the data lines 22. In this embodiment, at the positions where the scan lines 21 are overlapped with the data lines 22, the data lines 22 are located above the scan lines 21, with the gate insulating layer 23, a semiconductor layer 25 and a doped semiconductor layer 26 being sequentially arranged between the data lines 22 and the scan lines 21. In other implementations, at the positions where the scan lines are overlapped with the data lines, merely the gate insulating layer is arranged between the data lines and the scan lines (similar to embodiment II).

In the box aligning process of the color filter substrate 1 and the array substrate 2, since the primary spacers 13 are higher than the secondary spacers 14, the free ends of the primary spacers 13 will abut against the array substrate 2. Moreover, the data lines 22 would be inserted into grooves formed between the paired primary spacers 13, so that each data line 22 is clamped between a pair of primary spacers 13. In this way, the data lines 22 may be positioned through the paired primary spacers 13, so that the data lines 22 may be accurately aligned with the black matrix 11. Therefore, the technical problem of light leakage caused by alignment deviation of the array substrate and the color filter substrate in the box aligning process can be solved.

After box aligning of the color filter substrate 1 and the array substrate 2, generally, only the primary spacers 13 are in contact with the array substrate 2 to play a main supporting role and maintain the box thickness between the color filter substrate 1 and the array substrate 2, whereas the secondary spacers 14 are not in contact with the array substrate 2. When the color filter substrate 1 is subjected to an external pressure, the secondary spacers 14 are in contact with the array substrate 2 to play an auxiliary supporting role.

It should be noted that, in other implementing modes, embodiment III may be combined with embodiment I or embodiment II. That is, paired primary spacers and paired secondary spacers may be simultaneously arranged on the color filter substrate, and then the color filter substrate may include the following four kinds of spacers.

(1) The paired primary spacers are higher. The paired primary spacers play a role in positioning the data lines in the box aligning process of the color filter substrate and the array substrate, and play a main supporting role after box aligning of the color filter substrate and the array substrate.

(2) The paired secondary spacers are lower (lower than the primary spacers in (1)). The paired secondary spacers play a role in positioning the data lines in the box aligning process of the color filter substrate and the array substrate, and play an auxiliary supporting role after box aligning of the color filter substrate and the array substrate.

(3) The separated (unpaired) secondary spacers are lower (may have the same heights as those in (2)). The separated secondary spacers play an auxiliary supporting role after box aligning of the color filter substrate and the array substrate.

(4) The separated (unpaired) primary spacers may have the same heights as those in (1), or have the same heights as the secondary spacers in (2) and (3), and bosses are correspondingly arranged on the array substrate. The separated primary spacers play a main supporting role after box aligning of the color filter substrate and the array substrate.

Although the implementations disclosed by the present disclosure are described above, the contents are implementations merely adopted to facilitate understanding of the present disclosure, rather than limiting the present disclosure. Any skilled in the art to which the present disclosure pertains may make any modifications and variations on the implementation form and detail without departing from the disclosed spirit and scope of the present disclosure, but the patent protection scope of the present disclosure shall be subject to the scope defined by the appended claims.

1. A color filter substrate, including a plurality of spacers, wherein at least one of the spacers is arranged at each of both sides of a data line on an array substrate.

2. The color filter substrate according to claim 1, wherein the difference between the distance between the spacers arranged at respective sides of the data line and the width of the data line is 2 to 5 microns.

3. The color filter substrate according to claim 1, wherein spacers in form of paired ones are arranged at respective side of the data line, with one spacer being arranged at each side of the data line.

4. The color filter substrate according to claim 3, wherein the pair of spacers is paired primary spacers or paired secondary spacers.

5. The color filter substrate according to claim 4, wherein the paired spacers are all paired secondary spacers, and the color filter substrate further includes primary spacers arranged on the substrate, the primary spacers corresponding to bosses on the array substrate in positions.

6. The color filter substrate according to claim 4, wherein the paired spacers are all paired primary spacers, and the color filter substrate further includes secondary spacers arranged on the substrate, the primary spacers being higher than the secondary spacers.

7. A display device, including an array substrate and a color filter substrate, wherein the color filter substrate includes a plurality of spacers, at least one of the spacers being arranged at each of both sides of a data line on the array substrate.

8. The display device according to claim 7, wherein scan lines and data lines are arranged on the array substrate in a crisscross manner, corresponding to the positions of the spacers arranged on both sides of the data lines, and also corresponding to the positions where the scan lines are overlapped with the data lines; and
at the overlapping positions, the data lines are located above the scan lines, with a gate insulating layer being arranged between the data lines and the scan lines.

9. The display device according to claim 8, wherein a semiconductor layer and a doped semiconductor layer are further arranged between the data lines and the gate insulating layer.

10. The display device according to claim 7, wherein bosses are arranged on the array substrate.

11. The display device according to claim 10, wherein each boss is formed by the semiconductor layer, the doped semiconductor layer and a metal layer.
